(19) United States
(12) Patent Application Publication
(10) Pub. No.: US 2022/0157670 A1
(43) Pub. Date: May 19, 2022

(54) METHOD AND APPARATUS FOR MONITORING OPERATING STATUS OF MACHINE, STORAGE MEDIUM, AND ELECTRONIC DEVICE

(71) Applicant: CHANGXIN MEMORY TECHNOLOGIES, INC., Hefei City (CN)

(72) Inventors: Yuxiang WU, Hefei City (CN); Lili WANG, Hefei City (CN)

(21) Appl. No.: 17/647,184

(22) Filed: Jan. 6, 2022

Related U.S. Application Data
(63) Continuation of application No. PCT/CN2021/112341, filed on Aug. 12, 2021.

(30) Foreign Application Priority Data
Nov. 18, 2020 (CN) 202011294106.9

(51) Int. Cl. H01L 21/66; H01L 21/67

(52) U.S. Cl. CPC H01L 22/30; H01L 21/67253

(57) ABSTRACT

The present disclosure belongs to the technical field of semiconductors, and provides a method and apparatus for monitoring an operating status of a machine, a storage medium, and an electronic device. The method includes: monitoring a product fabrication process in real time and obtaining a monitoring data set; extracting abnormal data points of a machine based on the monitoring data set; performing screening on the abnormal data points of the machine and obtaining target abnormal data points; presetting a quantity threshold corresponding to the target abnormal data points; and determining, based on a quantity of the target abnormal data points and the quantity threshold, whether to generate an alarm signal.

### CROSS-REFERENCE TO RELATED APPLICATIONS

This is a continuation of International Application No. PCT/CN2021/112341, filed on Aug. 12, 2021, which claims the priority to Chinese Patent Application No. 202011294106.9, titled “METHOD AND APPARATUS FOR MONITORING OPERATING STATUS OF MACHINE, STORAGE MEDIUM, AND ELECTRONIC DEVICE” and filed on Nov. 18, 2020. The entire contents of International Application No. PCT/CN2021/112341 and Chinese Patent Application No. 202011294106.9 are incorporated herein by reference.

### TECHNICAL FIELD

The present disclosure relates to the technical field of semiconductors, and in particular, to a method and apparatus for monitoring an operating status of a machine, a storage medium, and an electronic device.

### BACKGROUND

During semiconductor production and processing, sizes, structural characteristics, and the like of products will change to a certain extent due to some reasons, and such change will affect the quality of semiconductor products. During actual processing, there are many reasons for such change. Therefore, monitoring the entire processing process and collecting and analyzing a variety of data are crucial to ensure the product quality. Currently, a special data collection system is usually used to collect a variety of data in a process conducted by a semiconductor process device. For example, a product production process is tracked and analyzed by a statistical process control (SPC) system by using a mathematical statistics method, to find out and solve problems in time to ensure the product quality. In the prior art, the SPC system is used to monitor a semiconductor fabrication process, but the efficiency of determining an operating status of a machine and performing fault analysis by using the SPC system needs to be improved.

It should be noted that information disclosed in the above background section is used merely for a better understanding of the background of the present disclosure. Therefore, the background may include information that does not constitute the prior art known to persons of ordinary skill in the art.

### SUMMARY

According to a first aspect of the present disclosure: a method for monitoring an operating status of a machine, applied to product fabrication process monitoring, comprising:

monitoring a product fabrication process in real time and obtaining a monitoring data set;

extracting abnormal data points of a machine based on the monitoring data set;

performing screening on the abnormal data points of the machine, and obtaining target abnormal data points;

presetting a quantity threshold corresponding to the target abnormal data points; and

determining, based on a quantity of the target abnormal data points and the quantity threshold, whether to generate an alarm signal.

According to a second aspect of the present disclosure, an apparatus for monitoring an operating status of a machine is provided, including:

one or more processors; and

a storage device, configured to store one or more programs, wherein the one or more programs, when executed by the one or more processors, cause the one or more processors to execute operations of:

monitoring a product fabrication process in real time, and obtaining a monitoring data set;

extracting abnormal data points of a machine based on the monitoring data set;

performing screening on the abnormal data points of the machine, and obtaining target abnormal data points;

presetting a quantity threshold corresponding to the target abnormal data points; and

determining, based on a quantity of the target abnormal data points and the quantity threshold, whether to generate an alarm signal.

According to a third aspect of the present disclosure, a computer-readable medium is provided. The computer-readable medium stores a computer program. When the computer program is executed by a processor, the method according to the first aspect is implemented.

It should be understood that the above general description and the following detailed description are only exemplary and explanatory, and should not be construed as a limitation to the present disclosure.

### BRIEF DESCRIPTION OF THE DRAWINGS

The accompanying drawings that are incorporated in this specification and constitute a part of this specification illustrate the embodiments of the present disclosure, and serve to explain the principles of the present disclosure together with this specification. Apparently, the accompanying drawings in the following description show merely some embodiments of this application, and persons of ordinary skill in the art may still derive other drawings from these accompanying drawings without creative efforts.

FIG. 1 is a schematic flowchart of a method for monitoring an operating status of a machine according to an exemplary embodiment of the present disclosure;

FIG. 2 is a schematic flowchart of a method for monitoring an operating status of a machine according to another exemplary embodiment of the present disclosure;

FIG. 3 is a schematic flowchart of a step in a method for monitoring an operating status of a machine according to an exemplary embodiment of the present disclosure;

FIG. 4 is a schematic flowchart of a step in a method for monitoring an operating status of a machine according to another exemplary embodiment of the present disclosure;

FIG. 5 is a schematic flowchart of a step in a method for monitoring an operating status of a machine according to still another exemplary embodiment of the present disclosure;

FIG. 6 is a schematic diagram of a result of abnormal data points according to an exemplary embodiment of the present disclosure;

FIG. 7 is a schematic diagram of a result of abnormal data points according to another exemplary embodiment of the present disclosure;

FIG. 8 is a schematic diagram of a preset quantity threshold according to an exemplary embodiment of the present disclosure;

FIG. 9 is a schematic diagram of a viewed result of a quantity threshold setting standard corresponding to a machine according to an exemplary embodiment of the present disclosure;

FIG. 10 is a schematic diagram of a result of a quantity of target abnormal data points corresponding to a machine according to an exemplary embodiment of the present disclosure;

FIG. 11 is a schematic structural diagram of an apparatus for monitoring an operating status of a machine according to an exemplary embodiment of the present disclosure;

FIG. 12 is a schematic structural diagram of a computer storage medium according to an exemplary embodiment of the present disclosure; and

FIG. 13 is a schematic structural diagram of an electronic device according to an exemplary embodiment of the present disclosure.

### DETAILED DESCRIPTION

Exemplary implementations will be described below in further detail with reference to the accompanying drawings. However, the exemplary implementations can be implemented in various forms, and should not be construed as being limited to those described herein. On the contrary, these exemplary implementations are provided to make the present disclosure comprehensive and complete and to fully convey the concept manifested therein to persons skilled in the art. Same reference numerals in the figures indicate same or similar structures, and thus their detailed descriptions will be omitted. In addition, the accompanying drawings are merely exemplary illustrations of the present disclosure, and are not necessarily drawn to scale.

The exemplary embodiments are described more fully below with reference to the accompanying drawings. However, the exemplary embodiments may be implemented in various forms, and should not be construed as being limited to those described herein. On the contrary, these embodiments are provided to make the present disclosure more comprehensive and complete and to fully convey the concept manifested therein to persons skilled in the art. The described features, structures, or characteristics may be incorporated into one or more embodiments in any suitable manner. In the following description, many specific details are provided to give a full understanding of the embodiments of the present disclosure.

In the figures, for clarity, thicknesses of areas and layers may be exaggerated. Same reference numerals in the figures indicate same or similar structures, and thus their detailed descriptions will be omitted.

The described features, structures, or characteristics may be incorporated into one or more embodiments in any suitable manner. In the following description, many specific details are provided to give a full understanding of the embodiments of the present disclosure. However, persons skilled in the art will be aware that the technical solutions of the present disclosure may be practiced with one or more of the specific details omitted, or other methods, components, materials, and the like may be used. In other cases, well-known structures, materials, or operations are not shown or described in details to avoid obscuring main technical ideas of the present disclosure.

When a structure is “on” another structure, it may mean that the structure is integrally formed on the another structure, that the structure is “directly” disposed on the another structure, or that the structure is “indirectly” disposed on the another structure through another structure.

Terms “a”, “one”, and “the” are used to indicate the existence of one or more elements, components, or the like. Terms “include” and “have” are used to indicate an open-ended meaning of inclusion, and refer to that there may be other elements, components, or the like in addition to listed elements, components, or the like. Terms “first” and “second” are only used as markers and are not limited to a quantity of objects.

In a related technology, SPC is a common technology for tracking and analyzing changes in a semiconductor manufacturing process. Usually, a variety of data information based on products or processes is collected, and multiple charts are generated based on the data information, for example, a control chart with a control limit. Currently, in most cases, data information obtained by using an SPC system is displayed for one product or process. In addition, when an abnormal point occurs during a fabrication process, effective screening and analysis cannot be performed on the abnormal point in time. Consequently, whether the abnormal point is related to an operating status of a machine cannot be determined, thereby affecting the efficiency of fault analysis and abnormality excluding.

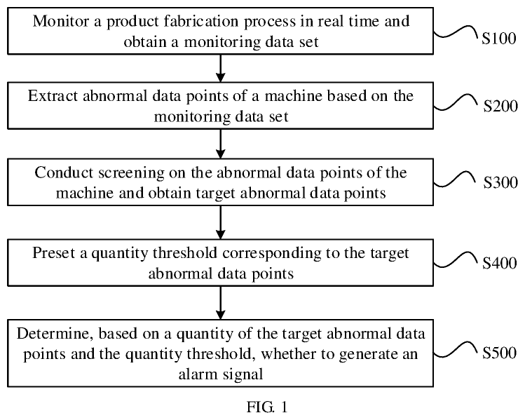

As shown in FIG. 1, the present disclosure provides a method for monitoring an operating status of a machine. The method is applied to product fabrication process monitoring, and includes:

Step S100. Monitor a product fabrication process in real time and obtain a monitoring data set.

Step S200. Extract abnormal data points of a machine based on the monitoring data set.

Step S300. Perform screening on the abnormal data points of the machine and obtain target abnormal data points.

Step S400. Preset a quantity threshold corresponding to the target abnormal data points.

Step S500. Determine, based on a quantity of the target abnormal data points and the quantity threshold, whether to generate an alarm signal.

The method for monitoring an operating status of a machine provided in the present disclosure is applied to product fabrication process monitoring. In a product fabrication process, when a control variable such as a critical dimension, an important process parameter, or the like of a product is abnormal, the method provided in the present disclosure helps to quickly determine whether the abnormality is related to a specific machine. The method for monitoring an operating status of a machine provided in the present disclosure includes: monitoring a product fabrication process in real time and obtaining a monitoring data set; extracting abnormal data points of a machine based on the monitoring data set; performing screening on the abnormal data points of the machine and obtaining target abnormal data points; presetting a quantity threshold corresponding to the target abnormal data points; and determining, based on a quantity of the extracted target abnormal data points and the quantity threshold, whether to generate an alarm signal. The abnormal data points of the machine are extracted from the monitoring data set, and some data points in the monitoring data set, for example, abnormal points beyond a control limit, are intuitively displayed by taking one machine as a unit, to facilitate subsequent corresponding determining of an operating status of the machine. Screening is performed on the abnormal data points of the machine to obtain the target abnormal data points, the quantity of the target abnormal data points is compared with the quantity threshold for determining, and a determining result is presented in a form of the alarm signal. In this step, an alerting standard of the machine is determined based on the target abnormal data points of the machine, and the operating status of the machine is reflected by using the alarm signal, intuitively providing operating status information of the machine. In the product fabrication process, according to the method for monitoring an operating status of a machine provided in the present disclosure, the operating status of the machine can be quickly determined by using the alarm signal. When the critical dimension, the important process parameter, or the like of the product is abnormal, the method is helpful for an engineer to quickly find out a cause of the abnormality, thereby improving the efficiency of excluding the abnormality and making the entire process enter a controllable state in time.

The steps in the method for monitoring an operating status of a machine provided in this implementation of the present disclosure are described in detail below with reference to the accompanying drawings.

In step S100, the product fabrication process is monitored in real time to obtain the monitoring data set.

In an exemplary embodiment of the present disclosure, the product fabrication process is monitored in real time by using an SPC system, to obtain the monitoring data set. The SPC system is configured to monitor the product fabrication process in real time. In the present disclosure, the SPC system may be specifically configured to monitor a semiconductor fabrication process in real time. Certainly, the SPC system is not limited to only SPC systems currently used by users. The SPC system may alternatively be other new systems that are developed by developers and that can implement SPC.

In this step, the SPC system collects related data in the product fabrication process, for example, a critical dimension of a product, an overlay error, and related technical parameters in the process, to obtain the monitoring data set. The critical dimension of the product may be a thickness, a width, a length, a weight, or the like of the product, and the related technical parameters in the process may be a temperature, time, a speed, and the like. Certainly, in addition to the critical dimension of the product, the overlay error, and the related technical parameters in the process, the monitoring data set in the present disclosure may include other data information that needs to be monitored, for example, a process node that is known based on previous data statistics and at which a relatively large quantity of unqualified products are produced. Specific data information to be monitored in the product fabrication process may be selected according to an actual requirement.

In the semiconductor fabrication process, the SPC system may be used for process monitoring. A semiconductor size, an overlay error, and related technical parameters in the process may be measured by a measuring machine or the like, and measured data is transmitted to the SPC system in real time. The SPC system obtains a monitoring data set in the semiconductor fabrication process based on the measured data, and stores the monitoring data set.

In step S200, the abnormal data points of the machine are extracted based on the monitoring data set.

In some exemplary embodiments of the present disclosure, an abnormal data point is a data point beyond a control limit or a specification limit, for example, a data point beyond a lower control limit (LCL) or an upper control limit (UCL), or a data point beyond an upper specification limit (USL) or a lower specification limit (LSL).

The control limit is determined based on the distribution of sample data monitored in the product fabrication process, and includes a UCL and an LCL. In the product fabrication process, when the SPC system is used for real-time monitoring, data information of a critical dimension of a product that affects the product quality or data information in a key fabrication process that affects the process quality is usually analyzed according to an actual requirement, and main data information that can represent the product quality or process quality is selected as a control object. A corresponding control chart that needs to be generated is select based on the control object and a control requirement, and the product fabrication process is analyzed by analyzing the control chart. Specifically, analysis and determining are performed based on positions and a variation trend of sample points formed by sample data. The control chart is a chart with a control limit, and the control limit may be obtained through calculation and analysis based on the sample data points. In the present disclosure, points beyond the control limit in the monitoring data set are classified as abnormal data points.

The specification limit is a specified limit value, and includes a USL and an LSL. The specification limit is usually artificially set by a technician based on a test result of key data information in a batch wafer process. Alternatively, a USL and an LSL of a critical dimension of a product may be set according to a customer requirement. In some embodiment of the present disclosure, points beyond the specification limit in the monitoring data set are classified as abnormal data points.

As shown in FIG. 3, in some embodiments of the present disclosure, step S200 includes:

Step S210. Extract abnormal data points in the product fabrication process based on the monitoring data set.

Step S220. Perform extraction by taking one machine as a unit, based on the abnormal data points in the product fabrication process, and obtain abnormal data points of the machine.

In step S210, the abnormal data points in the product fabrication process are extracted based on the monitoring data set. For example, in the semiconductor fabrication process, a critical dimension of a semiconductor product is monitored to obtain a monitoring data set about the critical dimension of the semiconductor product, and abnormal data points are extracted from the monitoring data set.

In an exemplary embodiment of the present disclosure, the abnormal data points in the product fabrication process are data points beyond a control limit or a specification limit. The abnormal data points may specifically include one or more of a data point beyond a UCL, a data point beyond an LCL, a data point beyond a USL, and a data point beyond an LSL, and may be specifically set by working personnel such as an engineer or a system administrator according to a requirement.

In step S220, extraction is performed by taking one machine as a unit, based on the abnormal data points in the product fabrication process, to obtain abnormal data points of the machine. In this step, extraction is performed by taking one machine as a unit, based on the abnormal data points to obtain abnormal data points corresponding to the machine. For example, in the semiconductor fabrication process, a critical dimension of a semiconductor product is monitored to obtain a monitoring data set of the critical dimension of the semiconductor product. The monitoring data set may usually include a machine name, a machine model, a product batch, a product number, and other information that are corresponding to the critical dimension of the semiconductor product. Abnormal data points are extracted from the monitoring data set, and extraction is performed by taking one machine as a unit, based on the abnormal data points. An extraction result may be displayed in a form of a graph, and then abnormal data points corresponding to the machine may be obtained. In addition, if key technical information in the semiconductor product process is monitored, abnormal data points corresponding to the machine may also be obtained. Specific steps are similar to those described above, and details are not described herein again.

It should be noted herein that step S210 and step S220 may be combined with each other, and an order between step S210 and step S220 may also be adjusted. For example, obtaining the abnormal data points of the machine based on the monitoring data set may alternatively include: performing extraction by taking one machine as a unit, based on the monitoring data set and obtaining a monitoring data set of the machine; and extracting abnormal data points of the machine based on the monitoring data set of the machine.

In step S300, screening is performed on the abnormal data points of the machine to obtain the target abnormal data points.

In some embodiments of the present disclosure, the target abnormal data points are to-be-analyzed abnormal data points. Abnormal data points may include a data point beyond a UCL, a data point beyond an LCL, a data point beyond a USL, and a data point beyond an LSL. One type of data points, for example, data points beyond the UCL, may be selected from the foregoing types of data points as target abnormal data points for analysis according to an actual requirement. In this case, the selected data points beyond the UCL are the target abnormal data points.

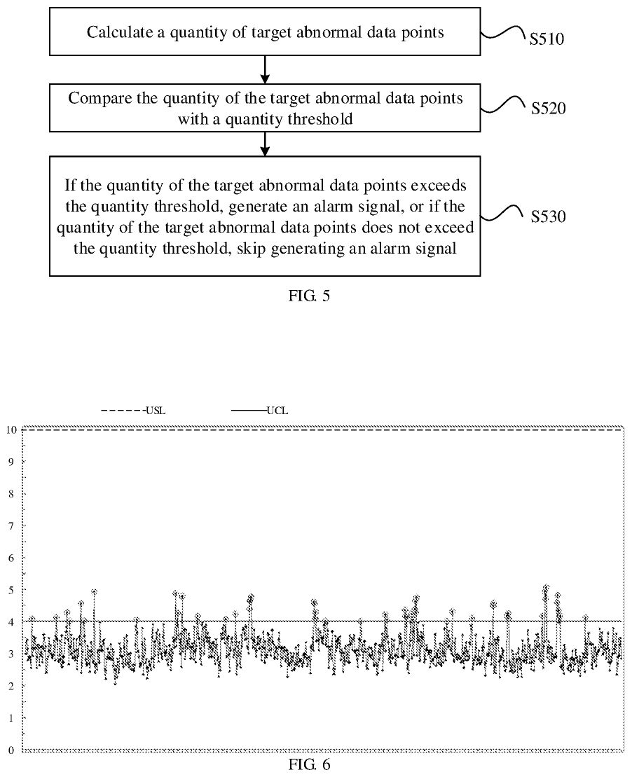

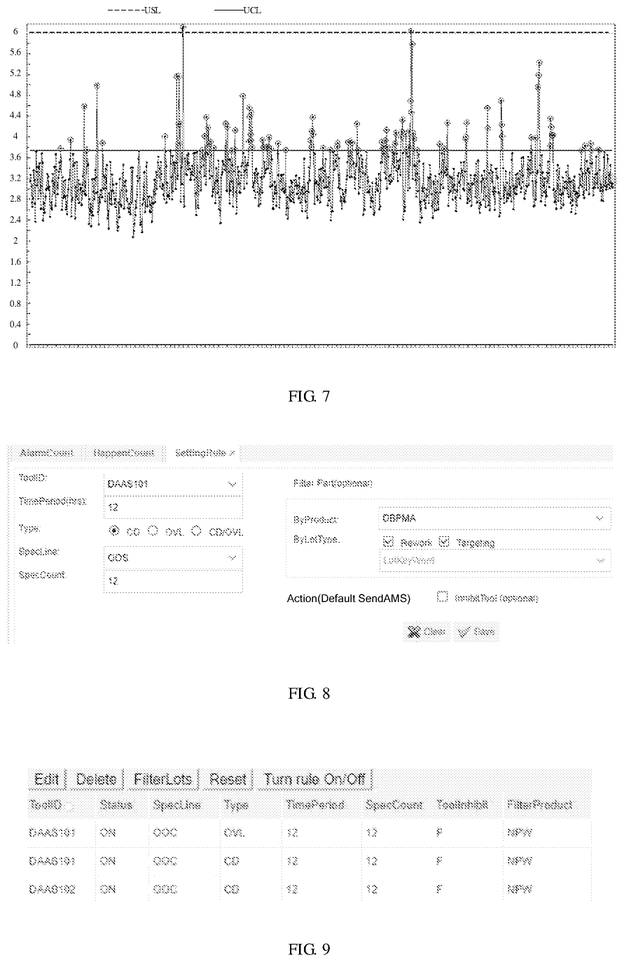

In some embodiments of the present disclosure, a data point beyond a control limit is denoted as OOC (Out of control), and a data point beyond a specification limit is denoted as OOS (Out of specification). In a specific embodiment, a data point beyond a UCL or a USL is used as a target abnormal data point. As shown in FIG. 6, in a specific embodiment of the present disclosure, a data point beyond a UCL is a target abnormal data point, that is, a point marked by ⊙. In another specific embodiment of the present disclosure, as shown in FIG. 7, points beyond a UCL and a USL are target abnormal data points, that is, points marked by ⊙. In FIG. 6 and FIG. 7, a horizontal ordinate represents time, and a vertical coordinate represents a collected data value. The figures illustrate only specific cases indicated by target abnormal data points, and a specific value of a data point in the figures does not constitute any limitation on the present disclosure. It should be noted herein that OOC and OOS are only specific markers in the specific embodiments; and in an actual use process, OOC and OOS may be set by a system administrator or the like according to an actual case. The OOC may include a data point beyond the UCL, and may also include a data point beyond an LCL. The OOS may include a data point beyond the USL, and may also include a data point beyond an LSL. In addition, in other embodiments of the present disclosure, a target abnormal data point may alternatively be a data point beyond the LCL or the LSL.

In some embodiments of the present disclosure, screening is performed on the abnormal data points of the machine at a preset time interval to obtain the target abnormal data points. The preset time is set according to an actual requirement. For example, it is specified that the abnormal data points of the machine are refreshed every 10 minutes. Extraction is performed on the abnormal data points of the machine to obtain the target abnormal data points. The preset time may be set according to progress of the product fabrication process. In the present disclosure, for different machines and different target abnormal data points, different preset times may be set.

As shown in FIG. 4, in some embodiments of the present disclosure, step S300 includes:

Step S310. Mark the abnormal data points of the machine with different labels based on types.

Step S320. Perform screening based on the labels and obtain the target abnormal data points.

In step S310, the abnormal data points of the machine are marked with different labels based on types. Generally, there may be multiple types of abnormal data points, for example, the data point beyond the UCL, the data point beyond the LCL, the data point beyond the USL, and the data point beyond the LSL. Different types of abnormal data points are marked. For example, the data point beyond the UCL and the data point beyond the LCL are marked with different labels.

In step S320, screening is performed based on the labels to obtain the target abnormal data points. For example, the data point beyond the UCL, the data point beyond the LCL, the data point beyond the USL, and the data point beyond the LSL are marked with different labels, for example, correspondingly marked with a label 1, a label 2, a label 3, and a label 4. To-be-analyzed target abnormal data points are selected according to an analysis requirement. If a data point beyond the UCL is selected as a target abnormal data point according to an actual case, an abnormal data point marked with the label 1 is selected, and the selected abnormal data point is recorded as a target abnormal data point.

In step S400, the quantity threshold corresponding to the target abnormal data points is preset.

The quantity threshold is a preset limit value of the quantity of the target data points. A specific value of the quantity threshold is not limited. In the present disclosure, for different machines and different target abnormal data points, there may be different quantity thresholds. As shown in FIG. 8, a quantity threshold (SpecCount) corresponding to target abnormal data points is preset to 12. In FIG. 8, for a machine whose machine ID (ToolID) is DAAS101, data is refreshed at a preset time interval to extract target abnormal data points, where the target abnormal data points are OOS. In this embodiment, OOS refers to an abnormal data point that is based on a critical dimension (CD) of a product and that is beyond a USL, and the preset time (TimePeriod) is 12 hrs. It should be noted herein that, during setting of the quantity threshold, product information may further be provided, such that in a subsequent operation process, an engineer may view a quantity threshold setting standard corresponding to a machine, a product, or the like according to an actual requirement. Specifically, as shown in FIG. 9, the figure shows quantity threshold setting standards corresponding to different machines.

In step S500, whether to generate an alarm signal is determined based on the quantity of the target abnormal data points and the quantity threshold.

In this step, the quantity of the target abnormal data points is compared with the quantity threshold for determining, and a determining result is presented in a form of the alarm signal. An operating status of the machine is reflected by using the alarm signal, such that an engineer can quickly determine the operating status of the machine.

As shown in FIG. 5, in some embodiments of the present disclosure, step S500 includes:

Step S510. Calculate the quantity of the target abnormal data points.

Step S520. Compare the quantity of the target abnormal data points with the quantity threshold.

Step S530. If the quantity of the target abnormal data points exceeds the quantity threshold, an alarm signal is generated; or if the quantity of the target abnormal data points does not exceed the quantity threshold, an alarm signal is not generated.

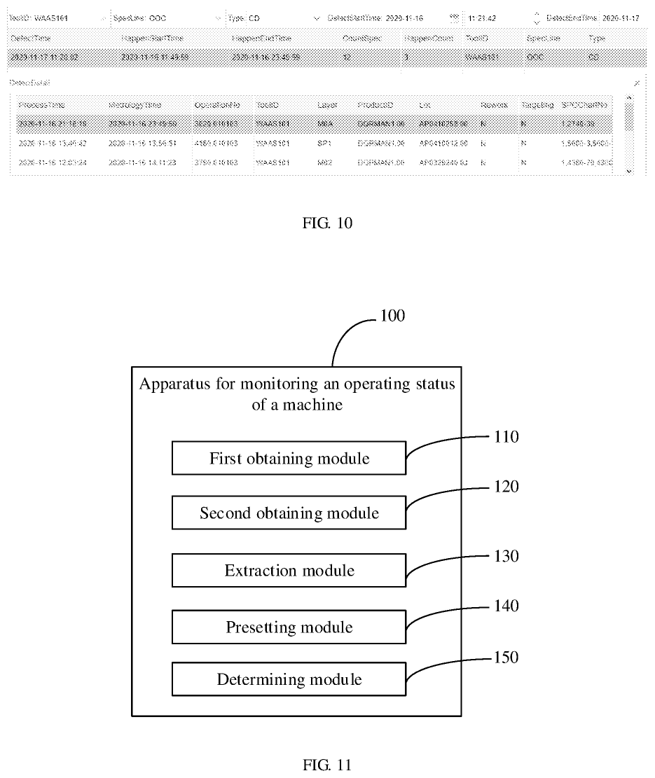

In step S510, the quantity of the target abnormal data points is calculated. The quantity of the target abnormal data points is a quantity of times the target abnormal points appear. The statistical result may be displayed in a form of a graph. For example, in a specific embodiment of the present disclosure, as shown in FIG. 10, a quantity (HappenCount) of target abnormal data points is 3. In the embodiment shown in FIG. 10, the target abnormal data points are data points (OOC) that are based on a critical dimension (CD) of a product and that are beyond a control limit, and a machine ID is WAAS101.

In step S520 and step S530, the quantity of the target abnormal data points is compared with the quantity threshold. The operating status of the machine is determined by comparing the quantity of the target abnormal data points and the quantity threshold. If the quantity of the target abnormal data points exceeds the quantity threshold, an alarm signal is generated, or if the quantity of the target abnormal data points does not exceed the quantity threshold, no alarm signal is generated. In the embodiment shown in FIG. 10, the quantity of the target abnormal data points is 3, a specified quantity threshold (SpecCount) is 12. In this case, the quantity of the target abnormal data points does not exceed the quantity threshold. Therefore, no alarm signal is generated. It should be noted herein that, in some embodiments of the present disclosure, a corresponding control chart may be viewed via a link based on specific data information in the chart shown in FIG. 10. In some embodiments, when a quantity of target abnormal data points exceeds a specified quantity threshold, an alarm signal is generated; an engineer can quickly find out, based on the alarm signal, a machine that generates the alarm signal, and view a corresponding control chart to analyze the control chart, to quickly find out a cause of an abnormality and exclude the abnormality, such that a product fabrication process is in a controllable state.

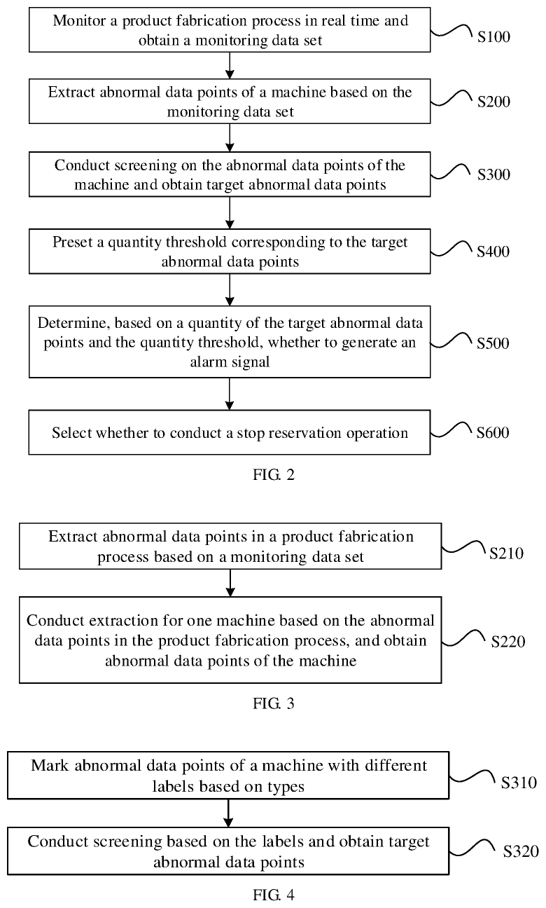

As shown in FIG. 2, in some embodiments of the present disclosure, the method for monitoring an operating status of a machine further includes:

Step S600. Select whether to perform a stop reservation operation.

If the stop reservation operation is selected to be performed, when the quantity of the target abnormal data points exceeds the quantity threshold, an alarm signal is generated, and the machine is allowed to stop running according to a preset stop reservation operation rule.

In this step, whether to perform the stop reservation operation may be selected during setting of the quantity threshold. As shown in FIG. 8, after the quantity threshold is set, whether to perform an operation corresponding to inhibitTool (optional), that is, the stop reservation operation, may be selected. In the present disclosure, the stop reservation operation refers to that the machine stops running according to the preset stop reservation operation rule. In some embodiments of the present disclosure, the stop reservation operation rule is that the machine stops running during fabrication of a next product or a next batch of products. Certainly, the stop reservation operation rule may alternatively be that the machine stops running after a period of time. The stop reservation operation rule may specifically be set according to a requirement of the product fabrication process.

In some embodiments of the present disclosure, if the stop reservation operation is selected to be performed, when the quantity of the target abnormal data points exceeds the quantity threshold, an alarm signal is generated, and the machine is allowed to stop running according to the preset stop reservation operation rule. If the stop reservation operation is not selected to be performed, the machine can continue running, and the machine does not stop running according to the preset stop reservation operation rule even if an alarm signal is generated when the quantity of the target abnormal data points exceeds the quantity threshold.

The present disclosure further provides an apparatus for monitoring an operating status of a machine. As shown in FIG. 11, in an embodiment of the present disclosure, the apparatus 100 for monitoring an operating status of a machine includes a first obtaining module 110, a second obtaining module 120, an extraction module 130, a presetting module 140, and a determining module 150.

The first obtaining module 110 is configured to monitor a product fabrication process in real time to obtain a monitoring data set.

The second obtaining module 120 is configured to extract abnormal data points of a machine based on the monitoring data set.

The extraction module 130 is configured to perform screening on the abnormal data points of the machine to obtain target abnormal data points.

The presetting module 140 is configured to preset a quantity threshold corresponding to the target abnormal data points.

The determining module 150 is configured to determine, based on a quantity of the target abnormal data points and the quantity threshold, whether to generate an alarm signal.

Specific details of the modules in the apparatus for monitoring an operating status of a machine have been described in detail in the corresponding method for monitoring an operating status of a machine. Therefore, details are not described herein again.

It should be noted that although several modules or units of a device for action execution are mentioned in the above detailed description, such division is not mandatory. Actually, according to the implementations of the present disclosure, features and functions of two or more modules or units described above can be embodied in one module or unit. On the contrary, features and functions of a module or unit described above can be further divided into multiple modules or units to be embodied.

Through the description of the above implementations, persons skilled in the art can easily understand that the exemplary embodiments described herein can be implemented by software, or can be implemented by combining software with necessary hardware. Therefore, the technical solution according to the implementations of the present disclosure can be embodied in a form of a software product. The software product may be stored in a non-volatile storage medium (which may be a CD-ROM, a USB flash drive, a removable hard disk, or the like) or on a network, and include several instructions to enable a computing device (which may be a personal computer, a server, a mobile terminal, a network device, or the like) to implement the method according to the implementations of the present disclosure.

An embodiment of the present disclosure further provides a computer storage medium that can implement the foregoing method. The computer storage medium stores a program product that can implement the foregoing method in this specification. In some possible implementations, various aspects of the present disclosure may also be implemented in a form of a program product, including program code. When the program product is run on a terminal device, the program code is used to enable the terminal device to execute steps described in the exemplary implementation in this specification.

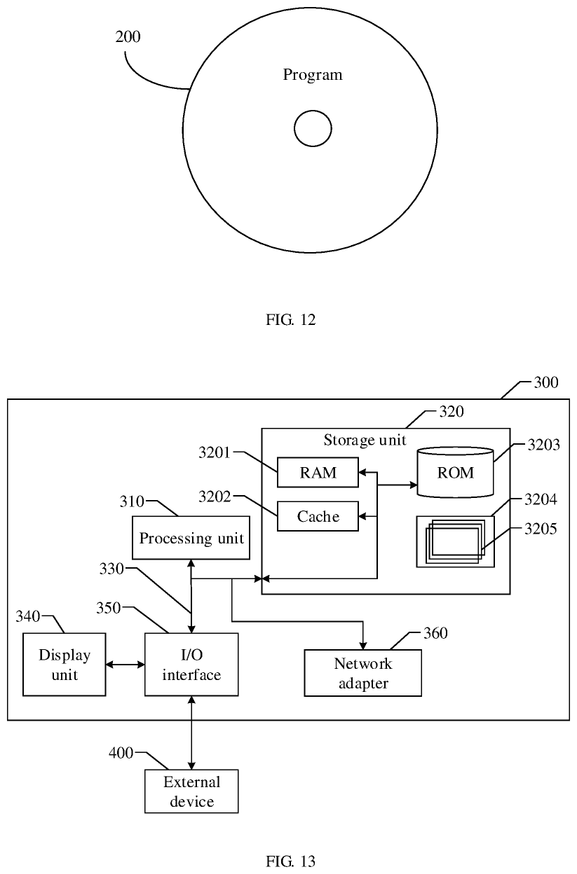

FIG. 12 shows a program product 200 used to implement the foregoing method according to an implementation of the present disclosure. The program product 200 may use a portable compact disk read-only memory (CD-ROM) and include program code, and may be run on a terminal device, for example, a personal computer. However, the program product in the present disclosure is not limited to this. In this document, the readable storage medium may be any tangible medium that includes or stores a program, and the program may be used by or in combination with an instruction execution system, apparatus, or device.

The program product may be any combination of one or more readable media. The readable medium may be a readable signal medium or a readable storage medium. The readable storage medium may be, for example, but is not limited to, an electrical, magnetic, optical, electromagnetic, infrared, or semiconductor system, apparatus, or device, or any combination of the above. More specific examples (a non-exhaustive list) of the readable storage medium include an electric connector with one or more wires, a portable magnetic disk, a hard drive, a random access memory (RAM), a read-only memory (ROM), an erasable programmable read-only memory (EPROM or flash drive), an optical fiber, a compact disk read-only memory (CD-ROM), an optical storage device, a magnetic storage device, or any proper combination of the above.

The computer-readable signal medium may include a data signal propagated in a baseband or propagated as a part of a carrier, and carries computer-readable program code. Such a propagated data signal may be in multiple forms, including, but not limited to an electromagnetic signal, an optical signal, or any proper combination of the above. The computer-readable signal medium may also be any computer-readable storage medium except the computer-readable medium. The computer-readable storage medium may send, propagate or transmit a program used by or used in combination with an instruction execution system, apparatus or device.

The program code included in the readable medium may be transmitted by using any suitable medium, including, but is not limited to radio, an electric wire, an optical fiber, RF, and the like, or any proper combination of the above.

Program code for executing the operations in the present disclosure may be compiled by using one or any combination of multiple program design languages. The programming languages include object oriented programming languages, such as Java and C++, and further include conventional procedural programming languages, such as the “C” language or similar programming languages. The program code can be executed fully on a user computing device, executed partially on user equipment, executed as an independent software package, executed partially on a user computing device and partially on a remote computing device, or executed fully on a remote computing device or a server. In a case in which a remote computing device is involved, the remote computing device may be connected to a user computing device via any type of network, including a local area network (LAN) or a wide area network (WAN), or may be connected to an external computing device (for example, connected via the Internet by using an Internet service provider).

In addition, an exemplary embodiment of the present disclosure further provides an electronic device that can implement the foregoing method.

Persons skilled in the art can understand that each aspect of the present disclosure can be implemented as a system, a method, or a program product. Therefore, each aspect of the present disclosure may be specifically implemented in the following forms, namely, a complete hardware implementation, a complete software implementation (including firmware, microcode, or the like), or a combination of hardware and software implementations. These implementations may be collectively referred to as “circuits”, “modules”, or “systems” herein.

An electronic device 300 according to this implementation of the present disclosure is described below with reference to FIG. 13. The electronic device 300 shown in FIG. 13 is only used as an example, and should not constitute any limitation to a function and an application range of the embodiments of the present disclosure.

As shown in FIG. 13, the electronic device 300 is represented in a form of a general-purpose computing device. Components of the electronic device 300 may include, but are not limited to, at least processing unit 310, at least one storage unit 320, and a bus 330 connected to different system components (including the storage unit 320 and the processing unit 310).

The storage unit 320 stores program code, and the program code can be executed by the processing unit 310, such that the processing unit 310 performs the steps described in various exemplary embodiments of the present disclosure. For example, the processing unit 310 may perform the following steps shown in FIG. 1: Step S100. Monitor a product fabrication process in real time and obtain a monitoring data set. Step S200. Extract abnormal data points of a machine based on the monitoring data set. Step S300. Perform screening on the abnormal data points of the machine and obtain target abnormal data points. Step S400. Preset a quantity threshold corresponding to the target abnormal data points. Step S500. Determine, based on a quantity of the target abnormal data points and the quantity threshold, whether to generate an alarm signal.

The storage unit 320 may include a readable medium in a form of a volatile storage unit, for example, a random access storage unit (RAM) 3201 and/or a cache storage unit 3202, and may further include a read-only storage unit (ROM) 3203.

The storage unit 320 may further include a program/utility tool 3204 including a set (at least one) of program modules 3205. Such program module 3205 includes, but is not limited to, an operating system, one or more application programs, another program module, and program data, and each of these examples or a combination of these examples may include an implementation of a network environment.

The bus 330 may represent one or more of several types of bus structures, including a storage unit bus, a storage unit controller, a peripheral bus, a graphics acceleration port, a processing unit, or a local bus using any one of multiple bus structures.

The electronic device 300 may also communicate with one or more external devices 400 (such as a keyboard, a pointing device, and a Bluetooth device), and may also communicate with one or more devices that enable a user to interact with the electronic device 300, and/or communicate with any device (such as a router and a modem) that enables the electronic device 300 to communicate with one or more other computing devices. Such communication may be performed through an input/output (I/O) interface 350. The I/O interface 350 may be connected to a display unit 340. In addition, the electronic device 300 may also communicate with one or more networks (such as a local area network (LAN), a wide area network (WAN), and/or a public network such as the Internet) through a network adapter 360. As shown in the figure, the network adapter 360 communicates with another module of the electronic device 300 through the bus 330. It should be understood that although not shown in the figure, other hardware and/or software modules, including but not limited to: microcode, a device driver, a redundancy processing unit, an external disk drive array, a RAID system, a tape drive, a data backup storage system, and the like, may be used in combination with the electronic device 300.

Through the description of the above implementations, persons skilled in the art can easily understand that the exemplary embodiments described herein can be implemented by software, or can be implemented by combining software with necessary hardware. Therefore, the technical solution according to the implementations of the present disclosure can be embodied in a form of a software product. The software product may be stored in a non-volatile storage medium (which may be a CD-ROM, a USB flash drive, a removable hard disk, or the like) or on a network, and include several instructions to enable a computing device (which may be a personal computer, a server, a terminal apparatus, a network device, or the like) to implement the method according to the implementations of the present disclosure.

The present disclosure is described with reference to the flowcharts and/or block diagrams of the method, the apparatus (device), and the computer program product according to the embodiments of the present disclosure. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, such that the instructions executed by a computer or a processor of any other programmable data processing device generate an apparatus for implementing a specific function in one or more processes in the flowcharts and/or in one or more blocks in the block diagrams.

These computer program instructions may also be stored in a computer readable memory that can instruct the computer or any other programmable data processing device to work in a specific manner, such that the instructions stored in the computer readable memory generate an artifact that includes an instruction apparatus. The instruction apparatus implements a specific function in one or more processes in the flowcharts and/or in one or more blocks in the block diagrams.

These computer program instructions may also be loaded onto a computer or another programmable data processing device, such that a series of operations and steps are performed on the computer or the another programmable device, thereby generating computer-implemented processing. Therefore, the instructions executed on the computer or the another programmable device provide steps for implementing a function specified in one or more processes in the flowcharts and/or in one or more blocks in the block diagrams.

It should be noted that although the steps of the method in the present disclosure are described in a specific order in the accompanying drawings, this does not require or imply that these steps need to be performed in the specific order or that a desired result can be achieved only after all the steps that are shown are performed. Additionally or alternatively, some steps may be omitted, multiple steps may be combined into one step, one step may be split into multiple steps, and/or the like, and all these cases should be regarded as a part of the present disclosure.

It should be understood that an application of the present disclosure is not limited to a detailed structure and arrangement form of the components proposed in this specification. The present disclosure can be implemented in other manners, and can be implemented in multiple manners. The foregoing variations and modifications fall within the scope of the present disclosure. It should be understood that the present disclosure disclosed and defined in this specification extends to all alternative combinations of two or more individual features mentioned or obvious in this specification and/or the accompanying drawings. All these different combinations constitute multiple alternative aspects of the present disclosure. The implementations in this specification illustrate known optimum manners for implementing the present disclosure, and persons skilled in the art can use the present disclosure according to these manners.

1. A method for monitoring an operating status of a machine, applied to product fabrication process monitoring, comprising:
monitoring a product fabrication process in real time and obtaining a monitoring data set;
extracting abnormal data points of a machine based on the monitoring data set;
performing screening on the abnormal data points of the machine, and obtaining target abnormal data points;
presetting a quantity threshold corresponding to the target abnormal data points; and
determining, based on a quantity of the target abnormal data points and the quantity threshold, whether to generate an alarm signal.

2. The method for monitoring an operating status of a machine according to claim 1, wherein the extracting abnormal data points of a machine based on the monitoring data set comprises:
extracting abnormal data points in the product fabrication process based on the monitoring data set, and
performing extraction by taking one machine as a unit, based on the abnormal data points in the product fabrication process, and obtaining abnormal data points of the machine.

3. The method for monitoring an operating status of a machine according to claim 1, wherein the performing screening on the abnormal data points of the machine, and obtaining target abnormal data points comprises:
marking the abnormal data points of the machine with different labels based on types; and
performing screening based on the labels, and obtaining the target abnormal data points.

4. The method for monitoring an operating status of a machine according to claim 1, wherein the performing screening on the abnormal data points of the machine, and obtaining target abnormal data points comprises:
performing screening on the abnormal data points of the machine at a preset time interval, and obtaining the target abnormal data points.

5. The method for monitoring an operating status of a machine according to claim 1, wherein the determining, based on a quantity of the target abnormal data points and the quantity threshold, whether to generate an alarm signal comprises:
calculating the quantity of the target abnormal data points;
comparing the quantity of the target abnormal data points with the quantity threshold; and
when the quantity of the target abnormal data points exceeds the quantity threshold, an alarm signal is generated; or when the quantity of the target abnormal data points does not exceed the quantity threshold, an alarm signal is not generated.

6. The method for monitoring an operating status of a machine according to claim 5, the method for monitoring an operating status of a machine further comprises:
selecting whether to perform a stop reservation operation; and
when the stop reservation operation is selected to be performed, when the quantity of the target abnormal data points exceeds the quantity threshold, an alarm signal is generated, and the machine stops running according to a preset stop reservation operation rule.

7. The method for monitoring an operating status of a machine according to claim 1, wherein the monitoring a product fabrication process in real time and obtaining a monitoring data set comprises:
monitoring the product fabrication process in real time by using a statistical process control system, and obtaining the monitoring data set.

8. An apparatus for monitoring an operating status of a machine, comprising:
one or more processors; and
a storage device, configured to store one or more programs, wherein the one or more programs, when executed by the one or more processors, cause the one or more processors to execute operations of:
monitoring a product fabrication process in real time, and obtaining a monitoring data set;
extracting abnormal data points of a machine based on the monitoring data set;
performing screening on the abnormal data points of the machine, and obtaining target abnormal data points;
presetting a quantity threshold corresponding to the target abnormal data points; and
determining, based on a quantity of the target abnormal data points and the quantity threshold, whether to generate an alarm signal.

9. A computer-readable storage medium, wherein the computer-readable storage medium stores a computer program; and when the computer program is executed by a processor, the method for monitoring an operating status of a machine according to claim 1 is implemented.
